(19) United States
(12) Patent Application Publication
(10) Pub. No.: US 2026/0282935 A1
(43) Pub. Date: Sep. 17, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Yen-Liang LIN, Hsinchu (TW); Yu Chi LIU, Taichung City (TW); Chin-I WANG, Tainan City (TW); Bo-Han CHU, Taipei City (TW); Hai-Dang TRINH, Hsinchu (TW); Yao-Wen CHANG, Taipei (TW); Chung-Yi YU, Hsin-Chu (TW)

(21) Appl. No.: 19/079,604

(22) Filed: Mar. 14, 2025

(51) Int. Cl. H01L 23/64; H01L 23/00; H01L 23/31; H01L 23/498; H01L 23/538; H01L 25/18; H10D 1/20

(52) U.S. Cl. CPC H10W 44/501; H10D 1/20; H10W 70/611; H10W 70/685; H10W 74/121; H10W 90/00; H10W 90/701; H10W 90/734

(57) ABSTRACT

An inductive device is manufactured to include a magnetic film scheme that increases the performance of the inductive device by increasing saturation current of the inductive device, decreasing hysteresis loss of the inductive device, and/or decreasing eddy current loss of the inductive device, among other examples. The inductive device may include a magnetic layer that includes a combination of metal elements that is doped with boron (B) to achieve low coercivity (H_{c}-resistance to becoming demagnetized) in the magnetic layer, which enables low hysteresis loss to be achieved for the inductive device. Additionally and/or alternatively to the combination of metal elements and boron doping, the magnetic layer may be doped with additional dopants such as nitrogen (N) and/or carbon (C) to increase the magnetic anisotropy of the magnetic layer and/or to increase the resistivity of the magnetic layer.

### BACKGROUND

An inductive device is a passive electronic component that is used in various electronic applications, such as radio frequency filters, alternating current (AC) blockers, voltage regulators, and/or transformers, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor package described herein.

FIG. 2 is a diagram of an example implementation of an inductive device described herein.

FIGS. 3A and 3B are diagrams of example implementations of material structures for a magnetic material described herein.

FIG. 4 is a diagram of an example implementation of grain size in a magnetic material described herein.

FIG. 5 is a diagram of an example implementation of dopant concentration in a magnetic material described herein.

FIG. 6 is a diagram of an example implementation of dopant diffusion rates of dopants that may be included in a magnetic material described herein.

FIG. 7 is a diagram of an example implementation of a hysteresis loop of an inductive device described herein.

FIGS. 8A-8J are diagrams of an example implementation of forming an inductive device described herein.

FIG. 9 is a flowchart of an example process associated with forming an inductive device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An inductive device may be designed with various parameters of the inductive device in mind, such as inductance, magnetic flux, saturation current, hysteresis loss, eddy current loss, and/or power loss, among other examples. “Saturation current” of an inductive device may refer to an electrical current at which the magnetic layers of the inductive device become saturated. When an inductive device reaches the saturation current, the inductive device experiences magnetic saturation and cannot further magnetize, thereby limiting the inductance of the inductive device. “Hysteresis loss” refers to energy loss in an inductive device due to hysteresis in transitions between magnetization and demagnetization of the inductive device. The greater the amount of hysteresis, the greater the hysteresis loss (and thus, the greater the energy loss). Eddy current loss can also occur an inductive device due to magnetic field changes. Eddy current loss may occur due to eddy currents that are induced in the inductive device, and those eddy currents may cause energy loss in the form of heat dissipation due to the resistance of the eddy currents to the changes in magnetic field.

In some implementations described herein, an inductive device is manufactured to include a magnetic film scheme that increases the performance of the inductive device by increasing saturation current of the inductive device, decreasing hysteresis loss of the inductive device, and/or decreasing eddy current loss of the inductive device, among other examples.

The inductive device may include a magnetic layer that includes a combination of metal elements that is doped with boron (B) to achieve low coercivity (H_{c}-resistance to becoming demagnetized) in the magnetic layer, which enables low hysteresis loss to be achieved for the inductive device. The low coercivity may be achieved in that the boron doping inhibits crystallization in the magnetic layer, which enables a smaller grain size to be achieved in the magnetic material of the magnetic layer. The smaller grain size enables magnetic flux to move more freely in the magnetic layer, thereby enabling the magnetic layer to more freely magnetize and demagnetize. This reduces the amount of hysteresis (and by extension, hysteresis loss) in transitions between magnetization and demagnetization for the inductive device.

Additionally and/or alternatively to the combination of metal elements and boron doping, the magnetic layer may be doped with additional dopants such as nitrogen (N) and/or carbon (C) to increase the magnetic anisotropy of the magnetic layer and/or to increase the resistivity of the magnetic layer. The increased magnetic anisotropy in the magnetic layer enables the inductive device to handle higher magnetic field strengths in particular magnetic field directions, which enables the inductive device to handle higher saturation current. The increased resistivity in the magnetic layer may reduce the effects of eddy currents in the inductive device, which may decrease eddy current loss in the inductive device.

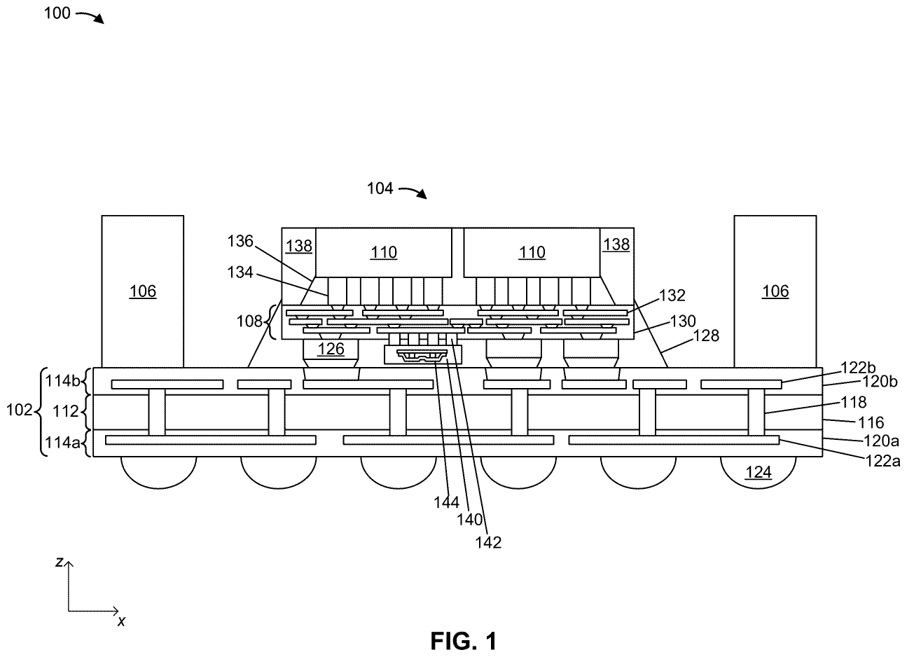

FIG. 1 is a diagram of an example semiconductor package 100 described herein. FIG. 1 illustrates a cross-section view in an x-direction in the semiconductor package 100. As shown in FIG. 1, the semiconductor package 100 includes a packaged semiconductor device that includes a package substrate 102 and one or more semiconductor die packages 104 bonded, attached, mounted, and/or otherwise secured to the package substrate 102. The semiconductor package 100 may be referred to as a 3D package, a 2.5D package, and/or another type of semiconductor package.

A stiffener structure 106 may be included over and/or on the package substrate 102. The semiconductor die package(s) 104 may be positioned within a perimeter of the stiffener structure 106 and may be spaced apart from the stiffener structure 106. The stiffener structure 106 may be included to reduce warpage and bending, and to maintain planarity of the package substrate 102. The stiffener structure 106 may include active circuitry, a non-active structure, or a combination thereof. The stiffener structure 106 may include one or more metal materials, one or more dielectric materials, and/or one or more materials of another material type.

A semiconductor die package 104 may include an interposer 108 and one or more integrated circuit (IC) dies 110 bonded, attached, mounted, and/or otherwise secured to the interposer 108. The quantity and arrangement of IC dies 110 illustrated in FIG. 1 is an example, and other quantities and arrangements are within the scope of the present disclosure. In some implementations, a semiconductor die package 104 may include a single IC die 110.

As shown in FIG. 1, the one or more IC dies 110 may be horizontally distributed (e.g., in an x-direction and/or in a y-direction) on the interposer 108. In some implementations, one or more of the IC dies 110 are active IC dies that include the active integrated circuits of the semiconductor die package 104 and perform the electrical and processing functions of the semiconductor die package 104. Examples of active IC dies include a logic IC die, a memory IC die, a high-bandwidth memory (HBM) IC die, an input/output (I/O) die, a system-on-chip (SoC) IC die, a dynamic random access memory (DRAM) IC die, a static random access memory (SRAM) IC die, a central processing unit (CPU) IC die, a graphics processing unit (GPU) IC die, a digital signal processing (DSP) IC die, an application specific integrated circuit (ASIC) IC die, and/or another type of active IC die. The active IC dies may have various sizes and/or shapes, and may be positioned in various locations and arrangements on the interposer 108.

In some implementations, one or more of the IC dies 110 are non-active dies. Examples of non-active dies include dummy dies and/or other types of non-active dies. A dummy die may also be referred to as an insertion die, a filler die, and/or another type of die that does not perform electrical and/or processing functions of the semiconductor die package 104. The quantity and/or positions of the non-active dies in the top view of the semiconductor die package 104 (e.g., the horizontal arrangement of non-active dies in the top view) may be determined and/or selected to achieve and/or satisfy one or more parameters for the semiconductor die package 104. Unused area (e.g., area that is not occupied by at least one IC die 110) in the horizontal arrangement of IC dies 110 in the semiconductor die package 104 may result in reduced stiffness and/or reduced rigidity for the semiconductor die package 104. This may increase the likelihood of bending, warpage, and/or physical damage to the semiconductor die package 104. Accordingly, the quantity and/or positions of the non-active dies may be determined and/or selected in order to reduce and/or minimize unused area in the horizontal arrangement of the IC dies 110. Thus, the non-active dies may be positioned in unused area between two or more active IC dies, may be positioned in unused area adjacent to (or next to) one or more active IC dies, or a combination thereof, to minimize unused area in the horizontal arrangement of IC dies 110 of the semiconductor die package 104.

As further shown in FIG. 1, the package substrate 102 of the semiconductor package 100 may include a substrate core 112 that is sandwiched between a redistribution structure 114a (e.g., a bottom redistribution layer (RDL)) and a redistribution structure 114b (e.g., a top RDL). Thus, the package substrate 102 may include a vertically arranged (e.g., in the z-direction) stack that includes the redistribution structure 114a, the substrate core 112, and the redistribution structure 114b.

The substrate core 112 may include substrate layer 116 and one or more interconnect structures 118 extending through the substrate layer 116. The substrate layer 116 may include a silicon (Si) substrate, a dielectric substrate, a polymer substrate, and/or another suitable substrate material. The interconnect structures 118 may include through hole vias (THVs), through integrated fanout vias (TIVs), through silicon vias (TSVs), and/or one or more other types of interconnect structures. The interconnect structures 118 may enable signals and/or power to be distributed between the redistribution structure 114a and the redistribution structure 114b.

As further shown in FIG. 1, the redistribution structure 114a may include an insulator layer 120a and a plurality of conductive structures 122a included in the insulator layer. The insulator layer 120a may include polyimide, polybenzoxazole (PBO), benzocyclobutene (BCB), an ajinomoto buildup film (ABF), a solder resist (SR) film, a pre-impregnated composite fiber (prepreg), a non-woven glass fabric, and/or another suitable insulator material.

In some implementations, the conductive structures 122a of the redistribution structure 144a may be arranged in a plurality of vertically stacked layers in the z-direction. The layers of conductive structures 122a may extend between a top side of the redistribution structure 114a facing the substrate core 112 and a second side of the redistribution structure 114a facing the bottom of the semiconductor package 100. The layers of conductive structures may include a plurality of alternating layers of metallization layers and interconnect layers. The metallization layers and the interconnect layers are electrically interconnected to provide a signal and/or power path throughout the redistribution structure 114a.

The metallization layers may include a combination of trenches, metallization layers, conductive traces, and/or other types of conductive structures. The interconnect layers may include a combination of vias, interconnects, and/or other types of conductive structures. The metallization layers and the interconnect layers may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

As further shown in FIG. 1, the redistribution structure 114b may similarly include an insulator layer 120b and conductive structures 122b (e.g., metallization layers and interconnect layers) that may be arranged in one or more layers in the insulator layer 120b. The layers of conductive structures may extend between a top side of the redistribution structure 114b facing the semiconductor die package(s) 104 and a second side of the redistribution structure 114b facing the substrate core 112. The layers of conductive structures may be interconnected to provide a signal and/or power path between the interconnect structures 118 and the semiconductor die package(s) 104.

As further shown in FIG. 1, package connection structures 124 may be included on the bottom of the redistribution structure 114a. The package connection structures 124 may include solder balls, ball grid array (BGA) balls, land grid array (LGA) pads, pin grid array (PGA) pins, and/or one or more other types of connection structures that enable the semiconductor package 100 to be attached (e.g., soldered, bonded, socketed) to another device or substrate.

As further shown in FIG. 1., the interposer 108 of the semiconductor die package 104 may be attached to the package substrate 102 (e.g., to conductive structures 122b of the redistribution structure 114b) of the semiconductor package 100 by a plurality of connection structures 126. The connection structures 126 may include a stud, a pillar, a bump, a solder ball, a micro-bump, an under-bump metallization (UBM) structure, and/or another type of connection structure, among other examples. The connection structures 126 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free).

An underfill material 128 may be included under the semiconductor die package 104 and between the connection structures 126 of the semiconductor die package 104. The underfill material 128 may include a polymer, one or more fillers dispersed in a resin, an epoxy-based resin, and/or another type of insulating material. The underfill material 128 may extend outward from the semiconductor die package 104 and toward the stiffener structure 106. For example, the underfill material 128 may extend outward in a tapered or sloped manner. As another example, the underfill material 128 may extend outward in a concave manner or in a convex manner.

The interposer 108 may include a base layer 130 and a plurality of conductive traces 132 (e.g., copper (Cu) traces, aluminum (Al) traces) in the base layer 130. The base layer 130 may be formed of one or more layers of a polymer material, a molding material, and/or a dielectric material (e.g., silicon oxide (SiOₓ such as SiO₂), undoped silicate glass (USG)). In some implementations, the interposer 108 includes a silicon interposer. In these implementations, the interposer 108 includes a plurality of conductive traces 132 (e.g., copper (Cu) traces) in a base layer 130 that is formed of silicon (Si).

The IC dies 110 may be attached to the interposer 108 by a plurality of connection structures 134. The connection structures 134 may include a stud, a pillar, a bump, a solder ball, a micro-bump, a UBM structure, and/or another type of connection structure, among other examples. The connection structures 134 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free).

The connection structures 134 may connect lands (e.g., pads) on bottom surfaces of the IC dies 110 to lands on a top surface of the interposer 108. In some implementations, the connection structures 134 may include one or more electrical connections for signaling (e.g., corresponding lands of the IC dies 110 and/or the interposer 108 are electrically connected to respective circuitry and/or traces of the IC dies 110 and/or the interposer 108). In some implementations, the connection structures 134 may include one or more mechanical connections for attachment purposes and/or spacing purposes (e.g., corresponding lands of the IC dies 110 and/or the interposer 108 are not electrically connected to respective circuitry and/or traces of the IC dies 110 and/or the interposer 108). In some implementations, one or more of the connection structures 134 may function both electrically and mechanically.

One or more types of filler materials may be included above the interposer 108 and in areas surrounding the IC dies 110 and/or surrounding the connection structures 134. For example, an underfill layer 136 may be included between the connection structures 134 under the IC dies 110 and between the connection structures 134 under the IC dies 110. As another example, an encapsulant layer (also referred to as a molding compound) 138 may be included over and/or on the interposer 108 and/or over and/or on portions of the underfill layer 136 around the perimeter of the semiconductor die package 104.

The underfill layer 136 may include a polymer, one or more fillers dispersed in a resin, an epoxy-based resin, and/or another type of insulating material. In some implementations, the underfill layer 136 fills in the gaps between the IC dies 110. In some implementations, the underfill layer 136 may fully fill the gaps approximately up to a top surface of the IC dies 110. The underfill layer 136 may extend outward from one or more of the IC dies 110 toward the perimeter of the semiconductor die package 104. For example, the underfill layer 136 may extend outwardly in a tapered or sloped manner. As another example, the underfill layer 136 may extend outward in a concave manner or in a convex manner.

The encapsulant layer 138 may include a polymer, one or more fillers dispersed in a resin, an epoxy-based resin, and/or another type of insulating material. In some implementations, the encapsulant layer 138 may fully surround the top surfaces of the IC dies 110 such that the encapsulant layer 138 protects the IC dies 110 in the semiconductor die package 104.

As further shown in FIG. 1, an integrated passive device (IPD) package 140 may be coupled to the semiconductor die package 104. For example, the IPD package 140 may be electrically coupled to one or more conductive traces 132 of the interposer. In some implementations, the IPD package 140 is attached to a side of the interposer 108 opposing the side to which the IC dies 110 are attached. In these implementations, the IPD package 140 may be located vertically between the package substrate 102 and the semiconductor die package 104. In some implementations, the IPD package 140 is attached to the same side of the interposer 108 as the IC dies 110. In some implementations, an IPD package 140 is coupled to the package substrate 102 (e.g., to the redistribution structure 114a and/or 114b).

The IPD package 140 may be attached to the interposer 108 by a plurality of connection structures 142. The connection structures 142 may include a stud, a pillar, a bump, a solder ball, a micro-bump, a UBM structure, and/or another type of connection structure, among other examples. The connection structures 142 may include one or more materials, such as a gold (Au) material, a copper (Cu) material, a silver (Ag) material, a nickel (Ni) material, a tin (Sn) material, a lead (Pb) material, or a palladium (Pd) material, among other examples.

The IPD package 140 is a packaged semiconductor device that includes one or more passive electrical devices. For example, the IPD package 140 may include an inductive device 144. In some implementations, the IPD package 140 additionally includes a capacitor, a resistor, a diode, and/or another type of electrically passive device. Additionally and/or alternatively to passive electrical devices being included in the IPD package 140, one or more passive electrical devices (e.g., one or more inductive devices 144) may be included in an IC die 110.

As indicated above, FIG. 1 is provided as an example. Other examples may differ from what is described with regard to FIG. 1.

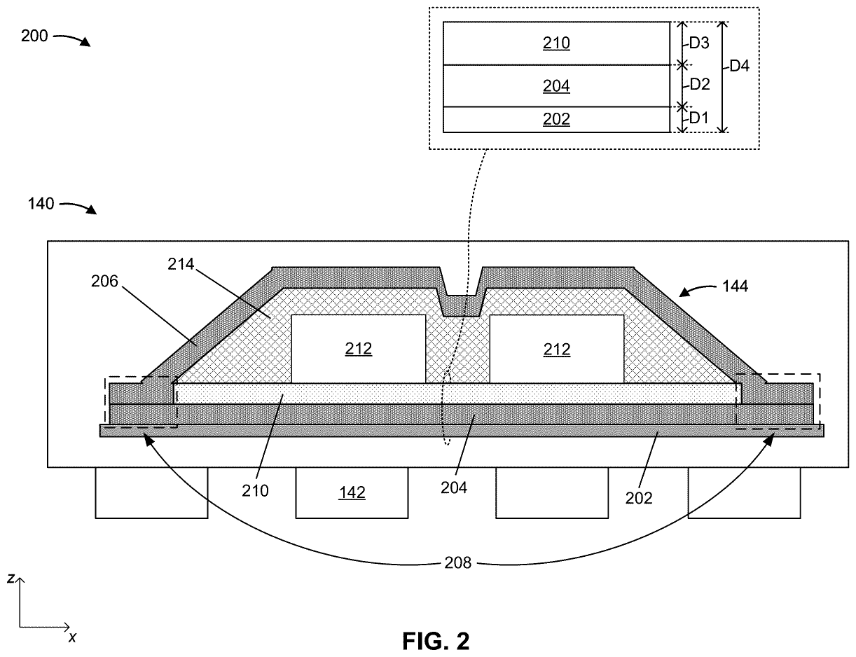

FIG. 2 is a diagram of an example implementation 200 of an inductive device 144 described herein. The inductive device 144 may be included in the IPD package 140 (as shown in the example in FIG. 2) and/or may be included in an IC die 110, among other examples. The inductive device 144 may be and/or include various types of inductive devices, such as an inductor, a coupled inductor, a coupled inductor voltage regulator (CLVR), a transformer, and/or another type of inductive device.

As shown in FIG. 2, the inductive device 144 may include an adhesion layer 202, a lower magnetic layer 204, and an upper magnetic layer 206. The lower magnetic layer 204 and the upper magnetic layer 206 may be in contact with each other in wing regions 208 of the inductive device 144, which forms a continuous magnetic layer (e.g., a magnetic shell) around various internal components of the inductive device 144, such as an isolation layer 210, one or more conductors 212, and a fill layer 214. The wing regions 208 may be lateral regions of the inductive device 144 on opposing sides (e.g., opposing lateral sides) in which the lower magnetic layer 204 and the upper magnetic layer 206 are in contact with each other.

The adhesion layer 202 may be included to promote adhesion between the lower magnetic layer 204 and the body of the IPD package 140. In some implementations, the adhesion layer 202 includes a metal-containing material. For example, the adhesion layer may include a metal such as aluminum (Al), tantalum (Ta), titanium (Ti), and/or tungsten (W), among other examples.

The lower magnetic layer 204 and the upper magnetic layer 206 may each include a magnetic material. In some implementations, the lower magnetic layer 204 and the upper magnetic layer 206 include the same magnetic material. In some implementations, the lower magnetic layer 204 and the upper magnetic layer 206 include different magnetic materials.

The magnetic material of the lower magnetic layer 204 and/or of the upper magnetic layer 206 may include a plurality of metal elements that are doped with one or more types of dopants. For example, the magnetic material of the lower magnetic layer 204 and/or of the upper magnetic layer 206 may include cobalt (Co), iron (Fe), and/or a combination thereof.

In some implementations, the metal elements included in the magnetic material of the lower magnetic layer 204 and/or of the upper magnetic layer 206 are different than the metal elements included in the adhesion layer 202. In other words, the magnetic material of the lower magnetic layer 204 and/or of the upper magnetic layer 206 may be free of the metal elements included in the material of the adhesion layer 202. As an example, the adhesion layer 202 may include a layer of aluminum (Al), and the lower magnetic layer 204 and/or the upper magnetic layer 206 may include a layer of cobalt and iron doped with boron (CoₐFe_{b}B_{c}) that is free of aluminum (Al). In this example, the layer of aluminum (Al) of the adhesion layer 202 may also be free of cobalt and iron. As another example, the adhesion layer 202 may include a layer of tantalum (Ta), and the lower magnetic layer 204 and/or the upper magnetic layer 206 may include a layer of cobalt and iron doped with boron and at least one of nitrogen (N) and/or carbon (C) (CoₐFe_{b}B_{c}C/N_{d}) that is free of tantalum (Ta). In this example, the layer of tantalum (Ta) of the adhesion layer 202 may also be free of cobalt and iron.

In some implementations, the concentration of iron in the magnetic material of the lower magnetic layer 204 and/or of the upper magnetic layer 206 is approximately the same as the concentration of cobalt in the magnetic material of the lower magnetic layer 204 and/or of the upper magnetic layer 206. For example, a ratio of iron in the magnetic material of the lower magnetic layer 204 and/or of the upper magnetic layer 206 to cobalt in the magnetic material of the lower magnetic layer 204 and/or of the upper magnetic layer 206 may be approximately 1:1.

In some implementations, the concentration of iron in the magnetic material of the lower magnetic layer 204 and/or of the upper magnetic layer 206 is greater than the concentration of cobalt in the magnetic material of the lower magnetic layer 204 and/or of the upper magnetic layer 206. For example, a ratio of iron in the magnetic material of the lower magnetic layer 204 and/or of the upper magnetic layer 206 to cobalt in the magnetic material of the lower magnetic layer 204 and/or of the upper magnetic layer 206 may be greater than approximately 1:1 and up to approximately 14:3. However, other values and ranges are within the scope of the present disclosure.

In some implementations, a molecule of the magnetic material of the lower magnetic layer 204 and/or of the upper magnetic layer 206 may contain CoₐFe_{b}B_{c} or CoₐFe_{b}B_{c}C/N_{d}, where a and b combined is included in a range of 80 atoms to 85 atoms. For example, a molecule of the magnetic material may contain CoₐFe_{b}B_{c}, where a is 20 atoms and b is 60 atoms. However, other values and ranges are within the scope of the present disclosure.

The magnetic material of the lower magnetic layer 204 and/or of the upper magnetic layer 206 may be doped with boron to achieve a low coercivity in the inductive device 144. The boron doping may enable the structure of the lower magnetic layer 204 and/or the structure of the upper magnetic layer 206 to resist crystallization so that the structure of the lower magnetic layer 204 and/or the structure of the upper magnetic layer 206 remains amorphic with a smaller grain size than if the magnetic material of the lower magnetic layer 204 and/or of the upper magnetic layer 206 were to crystallize. The lower coercivity in the inductive device 144 may reduce the amount of hysteresis experienced in the inductive device 144 between magnetization and demagnetization, which may enable a low hysteresis loss to be achieved for the inductive device 144.

The metal elements may be doped with boron such that the dopant concentration of boron in the magnetic material of the lower magnetic layer 204 and/or of the upper magnetic layer 206 is included in a range of approximately 10% by atomic volume of the magnetic material to approximately 25% by atomic volume of the magnetic material. Concentrations of boron in the lower magnetic layer 204 and/or in the upper magnetic layer 206 less than approximately 10% may not sufficiently lower the coercivity (and thus, may not sufficiently lower the hysteresis loss) of the inductive device 144. Concentrations of boron in the lower magnetic layer 204 and/or in the upper magnetic layer 206 greater than approximately 25% may result in a detrimental decrease in magnetic anisotropy (and thus, a decrease in saturation current) of the inductive device 144. However, other values and ranges are within the scope of the present disclosure.

In some implementations, a molecule of the magnetic material may contain CoₐFe_{b}B_{c} or CoₐFe_{b}B_{c}C/N_{d}, where _{c} is included in a range of 0 atoms to 25 atoms. For example, a molecule of the magnetic material may contain CoₐFe_{b}B_{c}, where ₐ is 20 atoms, _{b} is 60 atoms, and _{c} is 20 atoms. However, other values and ranges are within the scope of the present disclosure. In some implementations, a ratio of ₐ to _{c} is included in a range of approximately 3:5 to approximately 40:1. However, other values and ranges are within the scope of the present disclosure. In some implementations, a ratio of _{b} to _{c} is included in a range of approximately 8:5 to approximately 70:1. However, other values and ranges are within the scope of the present disclosure.

The magnetic material of the lower magnetic layer 204 and/or of the upper magnetic layer 206 may be doped with nitrogen and/or carbon to achieve a high magnetic anisotropy in the inductive device 144 and/or to achieve a high resistivity in the inductive device 144. Nitrogen and carbon may have low diffusion coefficients for doping (e.g., lower than the diffusion coefficient of boron at a given temperature), which may enable the dopant diffusion of nitrogen and/or carbon to be highly controlled during deposition of the magnetic material of the lower magnetic layer 204 and/or of the upper magnetic layer 206. For example, the dopant diffusion of nitrogen and the dopant diffusion of carbon may both be less than the dopant diffusion of boron.

In some implementations, a molecule of the magnetic material may contain CoₐFe_{b}B_{c}C_{d}, CoₐFe_{b}B_{c}Nₑ, and/or CoₐFe_{b}B_{c}C_{d}Nₑ where _{d} and ₑ are each included in a range of 0 atoms to 25 atoms. For example, a molecule of the magnetic material may contain CoₐFe_{b}B_{c}Nₑ, where ₐ is 20 atoms, _{b} is 60 atoms, _{c}is 14 atoms, and ₑ is 6 atoms. However, other values and ranges are within the scope of the present disclosure. In some implementations, a ratio of ₐ to _{d} is included in a range of approximately 3:5 to approximately 20:1. However, other values and ranges are within the scope of the present disclosure. In some implementations, a ratio of b to d is included in a range of approximately 8:5 to approximately 35:1. However, other values and ranges are within the scope of the present disclosure. In some implementations, a ratio of a to e is included in a range of approximately 3:5 to approximately 20:1. However, other values and ranges are within the scope of the present disclosure. In some implementations, a ratio of b to e is included in a range of approximately 8:5 to approximately 35:1. However, other values and ranges are within the scope of the present disclosure.

In some implementations, c and d combined is included in a range of 15 atoms to 30 atoms. However, other values and ranges are within the scope of the present disclosure. In some implementations, c and e combined is included in a range of 15 atoms to 30 atoms. However, other values and ranges are within the scope of the present disclosure. In some implementations, In some implementations, a ratio of c to d is included in a range of approximately 2:25 to approximately 25:1. However, other values and ranges are within the scope of the present disclosure. In some implementations, a ratio of c to e is included in a range of approximately 2:25 to approximately 25:1. However, other values and ranges are within the scope of the present disclosure.

The isolation layer 210 may be included between the lower magnetic layer 204 and the conductor(s) 212. The isolation layer 210 may also be included between the lower magnetic layer 204 and the fill layer 214. The isolation layer 210 and the fill layer 214 may include one or more electrically-insulating materials that electrically insulate the conductor(s) 212 from each other, and electrically insulate the conductor(s) 212 from the lower magnetic layer 204 and the upper magnetic layer 206.

The fill layer 214 may be formed of one or more insulating and/or dielectric materials, such as silicon mononitride (SiN), silicon dioxide (SiO), polyimide, benzocyclobutene, and/or the like. The isolation layer 210 may include a dielectric material such as a metal-oxide dielectric material, a metal-nitride dielectric material, an oxide-semiconductor material such as silicon oxide (SiOₓ such as SiO₂), and/or another dielectric material. In some implementations, the isolation layer 210 contains a metal element that is different than the metal elements included in the magnetic material of the lower magnetic layer 204 and/or of the upper magnetic layer 206. In other words, the magnetic material of the lower magnetic layer 204 and/or of the upper magnetic layer 206 may be free of the metal elements included in the material of the isolation layer 210, and the isolation layer 210 may be free of the metal elements included in the magnetic material of the lower magnetic layer 204 and/or of the upper magnetic layer 206. As an example, the isolation layer 210 may include a layer of aluminum oxide (AlₓO_{y}), and the lower magnetic layer 204 and/or the upper magnetic layer 206 may include a layer of cobalt and iron doped with boron (CoₐFe_{b}B_{c}) that is free of aluminum (Al). In this example, the layer of aluminum oxide (AlₓO_{y}) of the isolation layer 210 may also be free of cobalt and iron, and the lower magnetic layer 204 and the upper magnetic layer 206 may be free of aluminum (Al). As another example, the isolation layer 210 may include a layer of aluminum nitride (AlN), and the lower magnetic layer 204 and/or the upper magnetic layer 206 may include a layer of cobalt and iron doped with boron (CoₐFe_{b}B_{c}) that is free of aluminum (Al). In this example, the layer of aluminum nitride (AlN) of the isolation layer 210 may also be free of cobalt and iron, and the lower magnetic layer 204 and the upper magnetic layer 206 may be free of aluminum (Al).

In some implementations, the adhesion layer 202 and the isolation layer 210 contain the same metal element. For example, the adhesion layer 202 may include aluminum (Al), and the isolation layer 210 may contain a nitride or an oxide of aluminum (e.g., aluminum oxide (AlₓO_{y}) and/or aluminum nitride (AlN)). In some implementations, the adhesion layer 202 and the isolation layer 210 contain different metal elements. For example, the adhesion layer 202 may include titanium (Ti), and the isolation layer 210 may contain a nitride or an oxide of aluminum (e.g., aluminum oxide (AlₓO_{y}) and/or aluminum nitride (AlN)). In some implementations, the adhesion layer 202 contains a metal element such as tungsten (W), and the isolation layer 210 contains a semiconductor oxide such as silicon dioxide (SiO₂).

In some implementations, a thickness of the adhesion layer 202 (indicated in FIG. 2 as dimension D1) may be included in a range of approximately 10 nanometers to approximately 500 nanometers. However, other values and ranges are within the scope of the present disclosure. In some implementations, a thickness of the lower magnetic layer 204 (indicated in FIG. 2 as dimension D2) may be included in a range of approximately 500 nanometers to approximately 19 microns. However, other values and ranges are within the scope of the present disclosure. In some implementations, a thickness of the isolation layer 210 (indicated in FIG. 2 as dimension D3) may be included in a range of approximately 10 nanometers to approximately 500 nanometers. However, other values and ranges are within the scope of the present disclosure. In some implementations, a combined thickness of the adhesion layer 202, the lower magnetic layer 204, and the isolation layer 210 (indicated in FIG. 2 as dimension D4) may be included in a range of approximately 5 microns to approximately 20 microns. However, other values and ranges are within the scope of the present disclosure.

The conductor(s) 212 may include one or more conductive traces, conductive wires, and/or other conductive members of inductive device 144. The conductor(s) 212 may be formed of one or more conductive materials, such as copper, gold, silver, and/or the like. In some implementations, the inductive device 144 includes two or more conductors 212, which may correspond to an input of inductive device 144 (e.g., Vᵢₙ) and an output from inductive device 144 (e.g., Vₒᵤₜ).

In this way, the inductive device 144 may include one or more conductors 212, a lower magnetic layer 204, and an upper magnetic layer 206, where the lower magnetic layer 204 and the upper magnetic layer 206 are in contact in one or more wing regions 208 of the inductive device 144 such that the lower magnetic layer 204 and the upper magnetic layer 206 form a continuous magnetic layer around the one or more conductors 212. An adhesion layer 202 may be included under the lower magnetic layer 204, an isolation layer 210 may be included above the lower magnetic layer 204 and between the lower magnetic layer 204 and the one or more conductors 212, and a fill layer 214 may be included between the one or more conductors 212 and the upper magnetic layer 206. The lower magnetic layer 204 and the upper magnetic layer 206 may both include a magnetic material containing a plurality of metal elements doped with boron (B), nitrogen (N), and/or carbon (C) to decrease the coercivity of the inductive device 144, to increase the magnetic anisotropy of the inductive device 144, and/or to increase the resistivity of the inductive device 144.

In some implementations, the isolation layer 210 may include a metal-oxide material that contains a metal element different than the plurality of metal elements included in the material of the lower magnetic layer 204 and the upper magnetic layer 206. In some implementations, the isolation layer 210 may include a metal-nitride material that contains a metal element different than the plurality of metal elements included in the material of the lower magnetic layer 204 and the upper magnetic layer 206. In some implementations, the isolation layer 210 may include a non-metal oxide material such as a silicon oxide (SiOₓ such as SiO₂) that contains a semiconductor element. In some implementations, the adhesion layer 202 may include a metal material that contains a metal element other than the plurality of metal elements included in the material of the lower magnetic layer 204 and the upper magnetic layer 206.

In some implementations, the lower magnetic layer 204 and the upper magnetic layer 206 both contain a magnetic material containing at least cobalt (Co), iron (Fe), boron (B), and a dopant (e.g., nitrogen (N), carbon (C)) having a diffusion coefficient that is less than a diffusion coefficient of the boron. In some implementations, a concentration of the dopant in the material of the lower magnetic layer 204 and the upper magnetic layer 206 is less than a concentration of the boron in the material of the lower magnetic layer 204 and the upper magnetic layer 206.

In some implementations, the lower magnetic layer 204, the upper magnetic layer 206, and the isolation layer 210 contain nitrogen (N). In some implementations, the adhesion layer 202 and the isolation layer 210 contain different metal elements (e.g., the adhesion layer 202 may contain tantalum (Ta), and the isolation layer 210 may contain aluminum (Al)). In some implementations, the adhesion layer 202 and the isolation layer 210 contain the same metal element (e.g., aluminum (Al)) that is different from the metal elements in the lower magnetic layer 204 and the upper magnetic layer 206.

As indicated above, FIG. 2 is provided as an example. Other examples may differ from what is described with regard to FIG. 2.

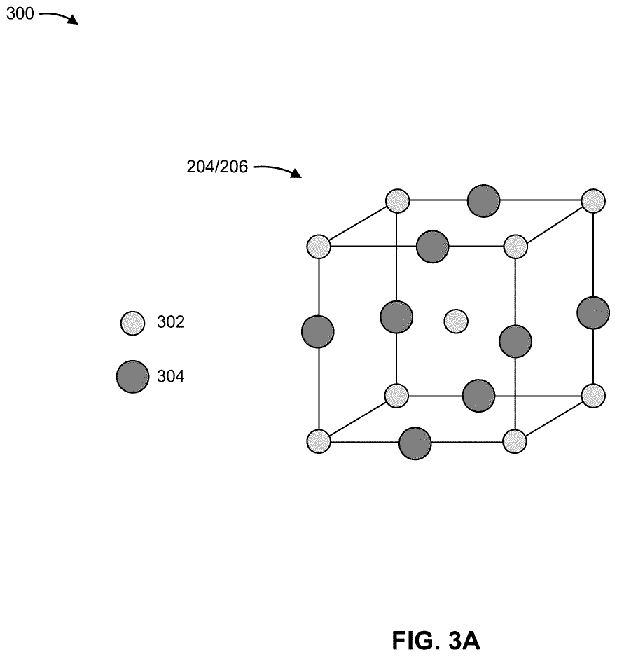

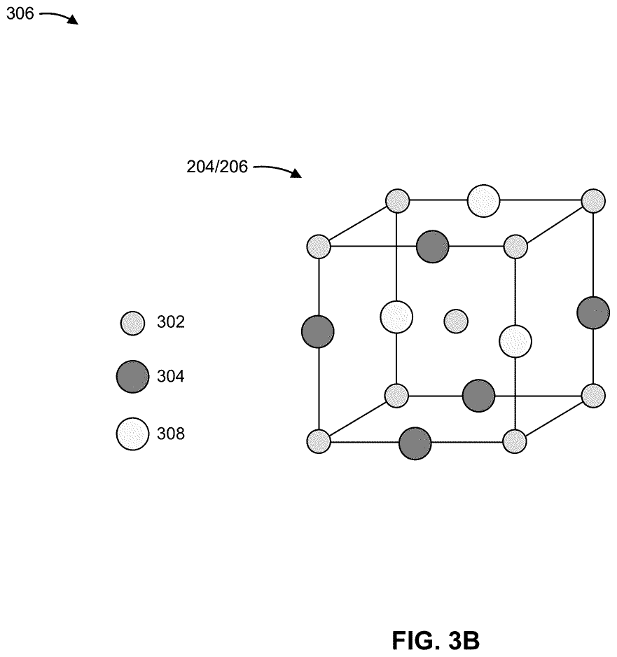

FIGS. 3A and 3B are diagrams of example implementations of material structures for a magnetic material described herein. The magnetic material may be included in the lower magnetic layer 204 and/or in the upper magnetic layer 206 of an inductive device 144 described herein.

FIG. 3A illustrates an example implementation 300 of a material structure. As shown in FIG. 3A, the material structure may include an arrangement of metal atoms 302. The metal atoms 302 may include cobalt (Co) and iron (Fe), among other examples. Dopant atoms 304 may occupy octahedral sites in the material structure, and therefore may be interstitial atoms in the material structure. The dopant atoms 304 may include boron atoms that are included to achieve a small grain size in the material structure by inhibiting the metal atoms 302 from crystallizing.

FIG. 3B illustrates an example implementation 306 of a material structure. As shown in FIG. 3B, the material structure may include an arrangement of metal elements 302. The metal atoms 302 may include cobalt (Co) and iron (Fe), among other examples. Dopant atoms 304 and 308 may occupy octahedral sites in the material structure, and therefore may be interstitial atoms in the material structure. The dopant atoms 304 may include boron (B) atoms that are included to achieve a small grain size in the material structure by inhibiting the metal atoms 302 from crystallizing. The dopant atoms 308 may include nitrogen (N) atoms and/or carbon (C) atoms that are included to achieve a high resistivity and/or a high magnetic anisotropy in the inductive device 144. In some implementations, the combination of boron and nitrogen/carbon doping may enable a magnetic anisotropy of greater than approximately 40 oersteds and a coercivity of less than approximately 1 oersted to be achieved for the inductive device 144. However, other values and ranges are within the scope of the present disclosure.

As indicated above, FIGS. 3A and 3B are provided as examples. Other examples may differ from what is described with regard to FIGS. 3A and 3B.

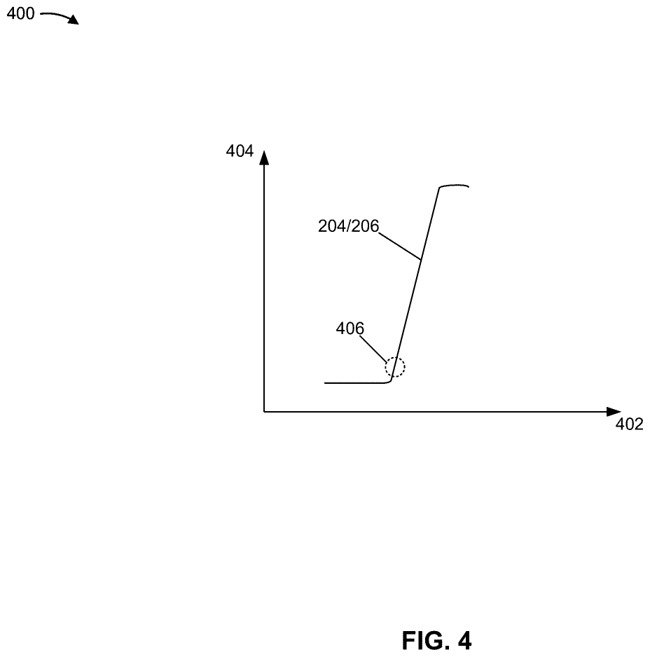

FIG. 4 is a diagram of an example implementation 400 of grain size in a magnetic material described herein. The magnetic material may be included in the lower magnetic layer 204 and/or in the upper magnetic layer 206 of an inductive device 144 described herein.

As shown in FIG. 4, grain size 402 of the magnetic material of the lower magnetic layer 204 and/or of the upper magnetic layer 206 may impact coercivity 404 of the inductive device 144. In particular, larger grain sizes 402 for the magnetic material of the lower magnetic layer 204 and/or of the upper magnetic layer 206 may result in higher coercivity (and thus, greater hysteresis loss) for the inductive device 144. Conversely, smaller grain sizes 402 for the magnetic material of the lower magnetic layer 204 and/or of the upper magnetic layer 206 may result in lower coercivity (and thus, less hysteresis loss) for the inductive device 144. The boron doping in the magnetic material of the lower magnetic layer 204 and/or of the upper magnetic layer 206 described herein may inhibit crystallization in the magnetic material, which may enable an amorphous material structure with a small corresponding grain size (indicated in FIG. 4 by reference number 406) to be achieved in the lower magnetic layer 204 and/or in the upper magnetic layer 206.

As indicated above, FIG. 4 is provided as an example. Other examples may differ from what is described with regard to FIG. 4.

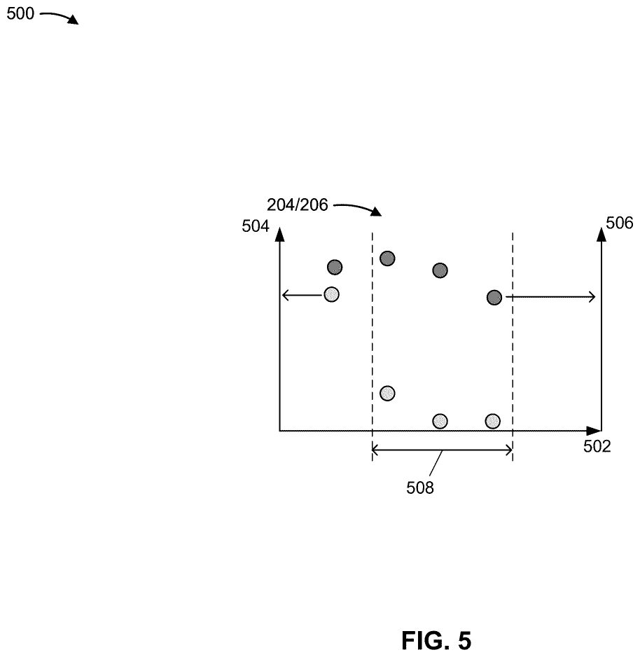

FIG. 5 is a diagram of an example implementation 500 of dopant concentration in a magnetic material described herein. The magnetic material may be included in the lower magnetic layer 204 and/or in the upper magnetic layer 206 of an inductive device 144 described herein.

As shown in FIG. 5, the dopant concentration 502 of boron in the magnetic material of the lower magnetic layer 204 and/or the upper magnetic layer 206 described herein may affect coercivity 504 and magnetic anisotropy 506 of the inductive device 144. For example, increasing the dopant concentration 502 of boron in the magnetic material of the lower magnetic layer 204 and/or of the upper magnetic layer 206 may decrease coercivity 504 and may also decrease magnetic anisotropy 506 of the inductive device 144. Conversely, decreasing the dopant concentration 502 of boron in the magnetic material of the lower magnetic layer 204 and/or the upper magnetic layer 206 may increase coercivity 504 and may increase magnetic anisotropy 506 of the inductive device 144.

As further shown in FIG. 5, if the dopant concentration 502 of boron is in a range 508 indicated in FIG. 5, the coercivity 504 of the inductive device 144 may be greatly decreased with minimal decrease in magnetic anisotropy 506 of the inductive device 144. This enables hysteresis loss to be greatly decreased for the inductive device 144 while still enabling a high magnetic anisotropy (and a correspondingly high saturation current) to be achieved for the inductive device 144.

As indicated above, FIG. 5 is provided as an example. Other examples may differ from what is described with regard to FIG. 5.

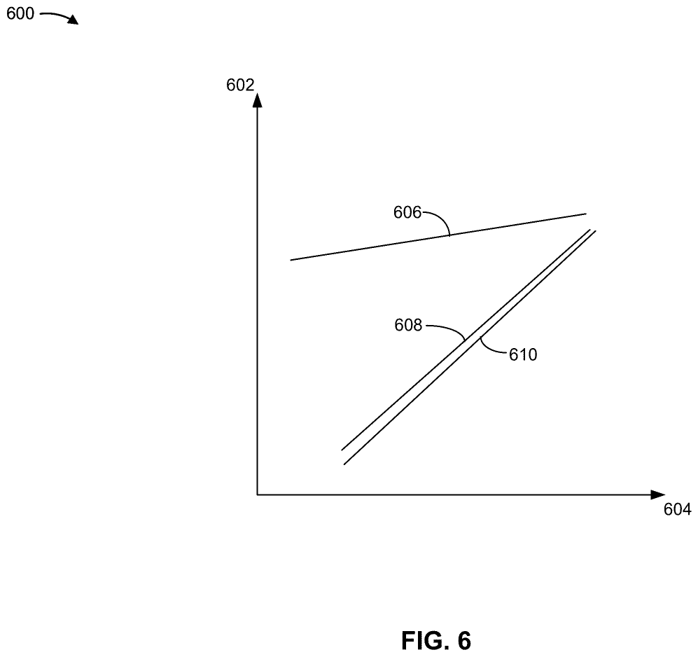

FIG. 6 is a diagram of an example implementation 600 of dopant diffusion rates of dopants that may be included in a magnetic material described herein. The magnetic material may be included in the lower magnetic layer 204 and/or in the upper magnetic layer 206 of an inductive device 144 described herein.

As shown in FIG. 6, diffusion coefficients 602 (which may correspond to the dopant diffusion rates) of dopants that may be included in a magnetic material of the lower magnetic layer 204 and/or the upper magnetic layer 206 may be dependent on a deposition temperature 604. In general, the diffusion coefficients 602 of boron 606, nitrogen 608, and carbon 610 may increase as the deposition temperature 604 increases. However, for a given deposition temperature, the diffusion coefficient 602 of nitrogen 608 may be less than the diffusion coefficient 602 of boron 606, and the diffusion coefficient 602 of carbon 610 may be less than the diffusion coefficient 602 of boron 606.

As indicated above, FIG. 6 is provided as an example. Other examples may differ from what is described with regard to FIG. 6.

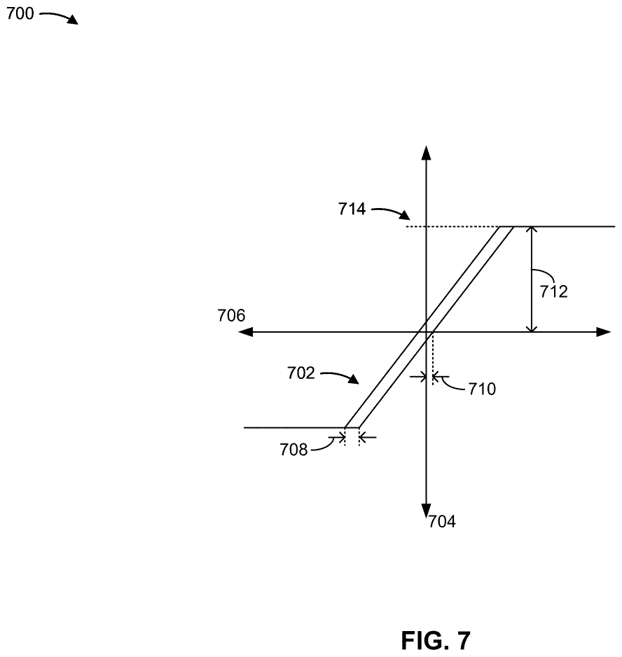

FIG. 7 is a diagram of an example implementation 700 of a hysteresis loop 702 of an inductive device 144 described herein. The hysteresis loop 702 is illustrated as a function of applied magnetic field 704 and magnetization 706.

As shown in FIG. 7, the hysteresis loop 702 contains some amount of hysteresis 708, which occurs due to a delay in response of changes in magnetization 706 to changes in the applied magnetic field 704. The hysteresis 708 results in a loss of energy each time the applied magnetic field 704 changes direction. The energy lost is dissipated as heat in the inductive device 144, contributing to hysteresis loss in the inductive device 144. The amount of hysteresis loss in the inductive device 144 is dependent on the amount of coercivity 710 in the inductive device 144. The greater the coercivity 710, the greater the disconnect between the applied magnetic field 704 and the magnetization of the inductive device 144, and the greater the hysteresis loss.

The magnetic material of the lower magnetic layer 204 and/or of the upper magnetic layer 206 of the inductive device 144 described herein includes a combination of metal elements (such as cobalt (Co) and iron (Fe)) that is doped with boron (B), nitrogen (N), and/or carbon (C) to achieve a low coercivity 710 in the inductive device 144. This, in turn, enables a low amount of hysteresis loss to be achieved in the inductive device 144.

Additionally and/or alternatively, the nitrogen (N) and/or carbon (C) doping in the lower magnetic layer 204 and/or of the upper magnetic layer 206 of the inductive device 144 enables a high magnetic anisotropy 712 to be achieved, which may correspond to a high difference between demagnetization and magnetic saturation 714 of the inductive device 144.

As indicated above, FIG. 7 is provided as an example. Other examples may differ from what is described with regard to FIG. 7.

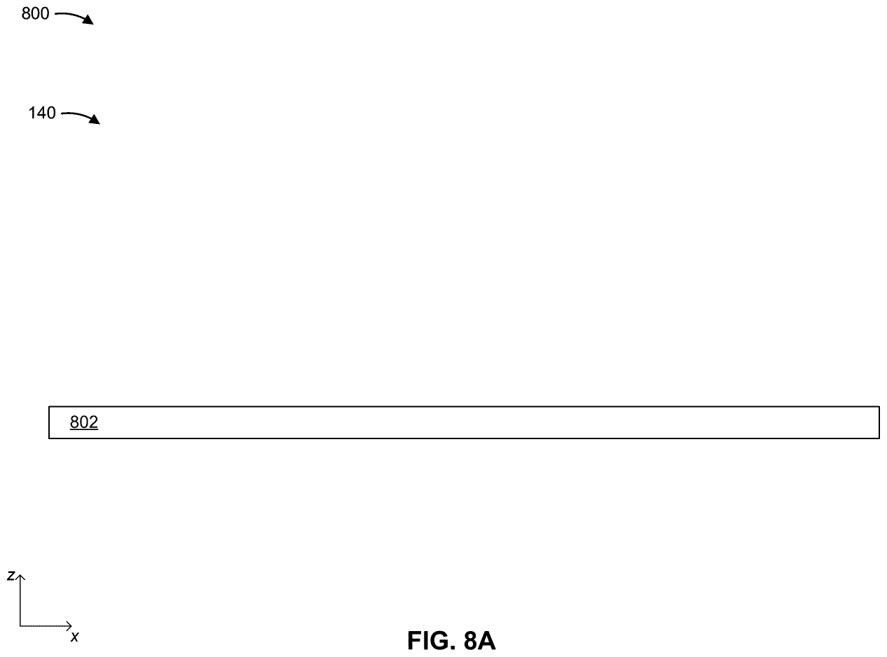

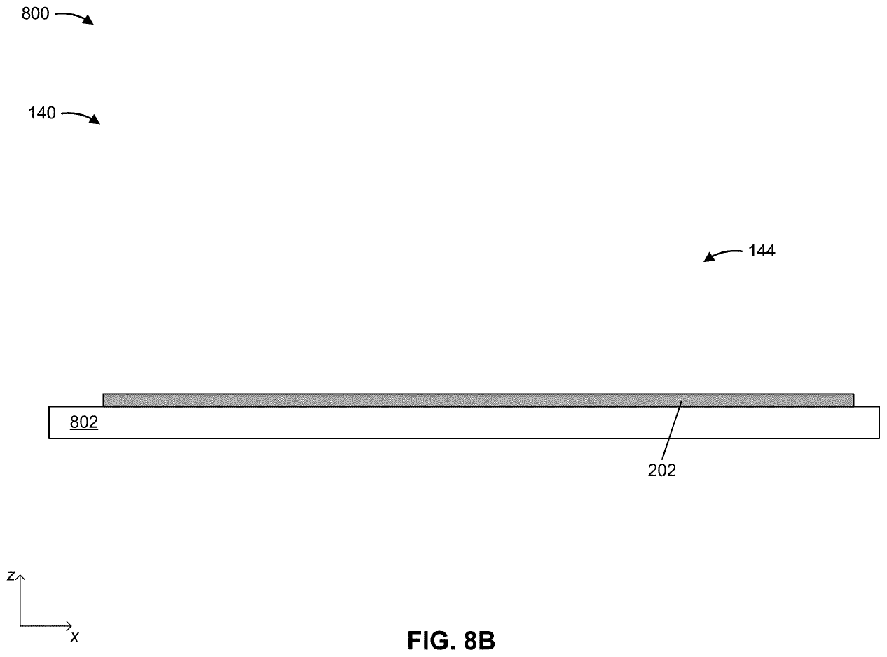

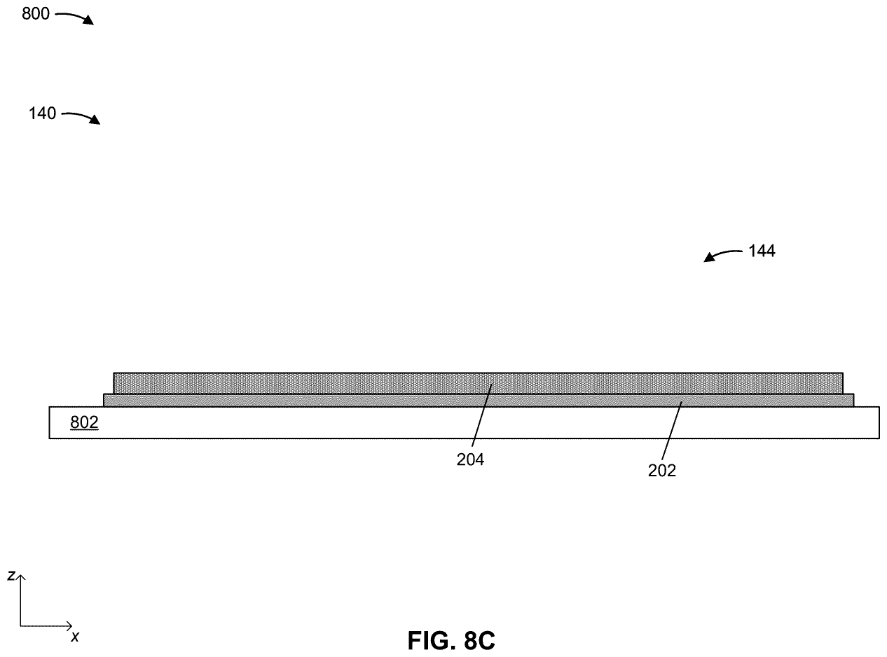

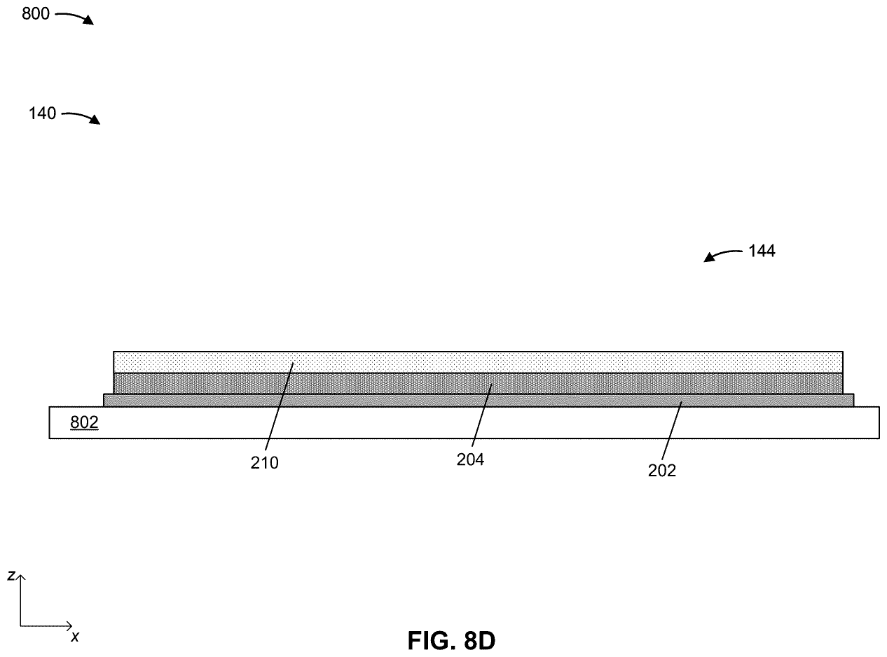

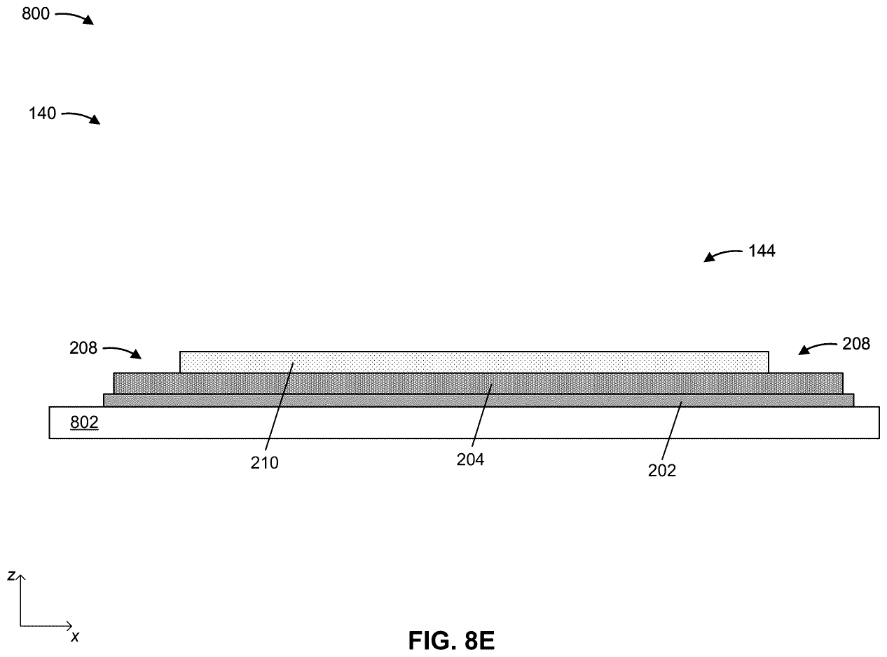

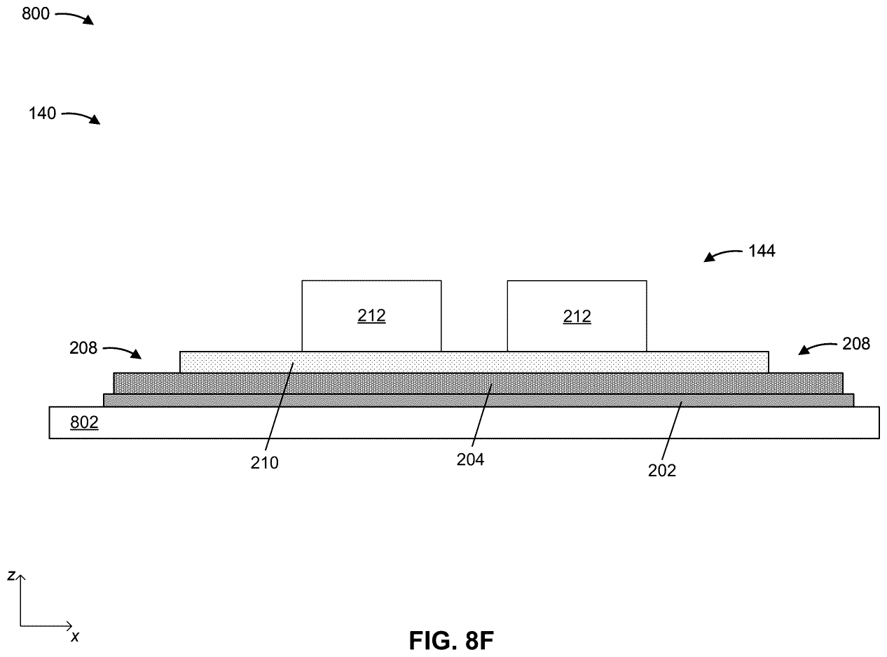

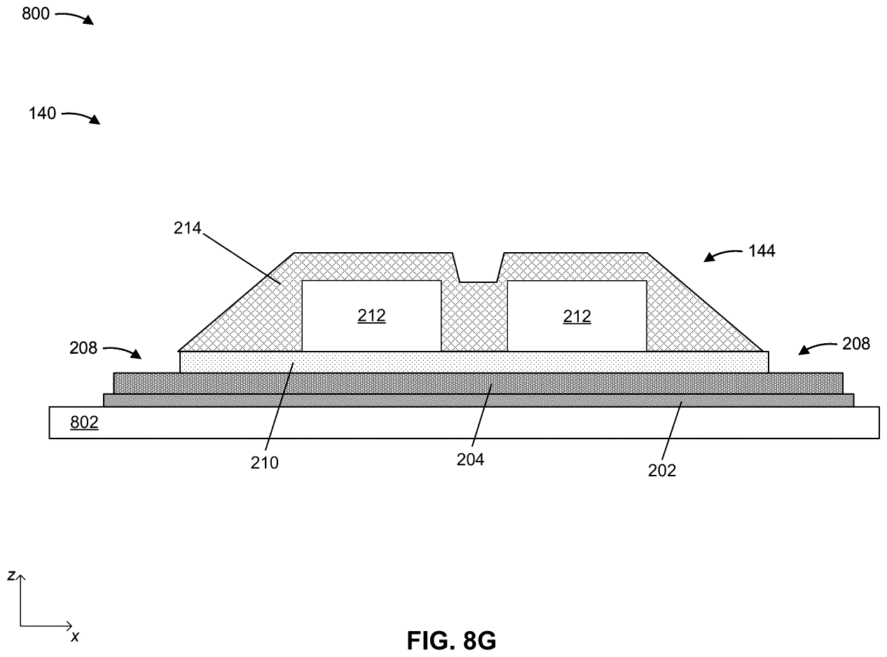

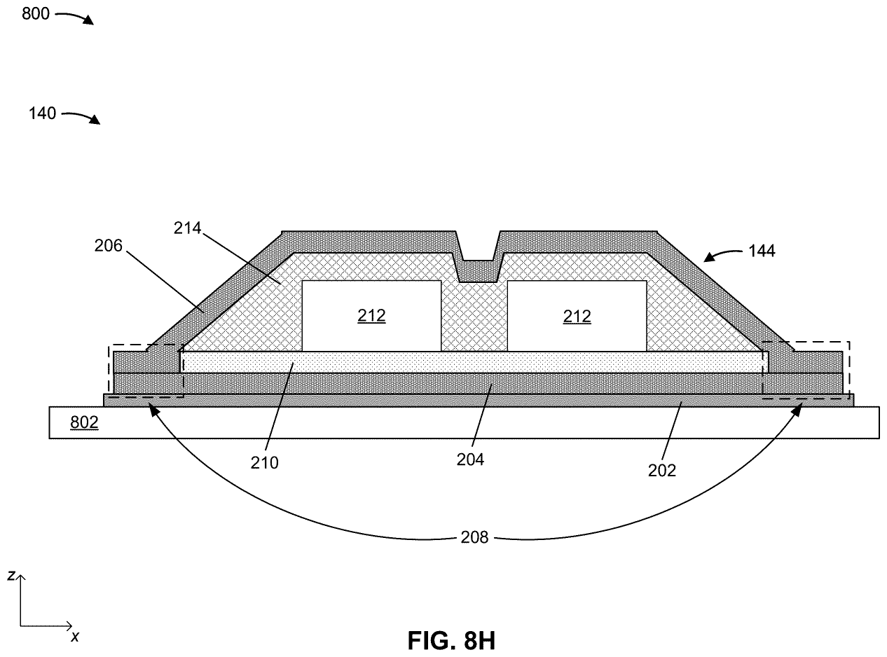

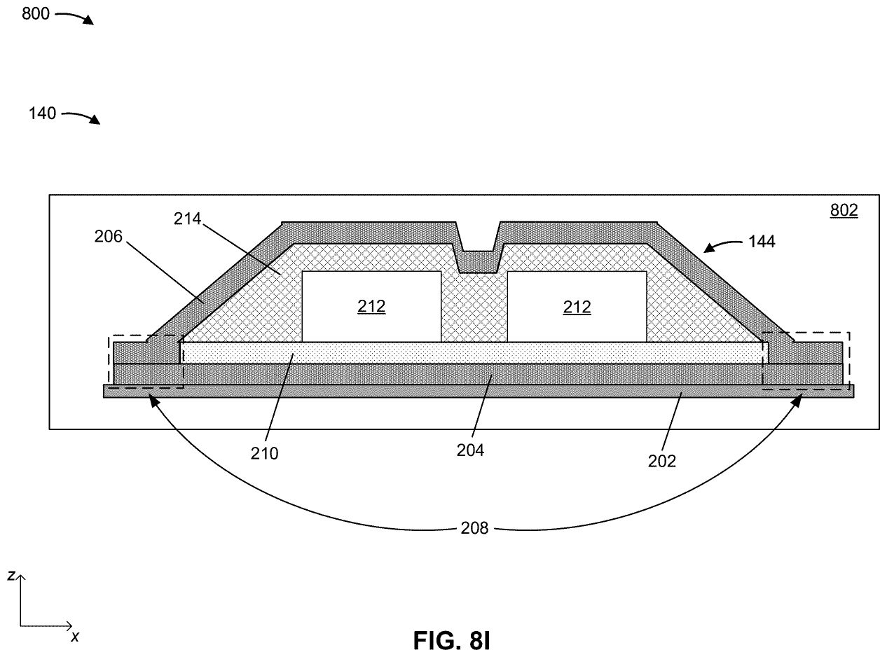

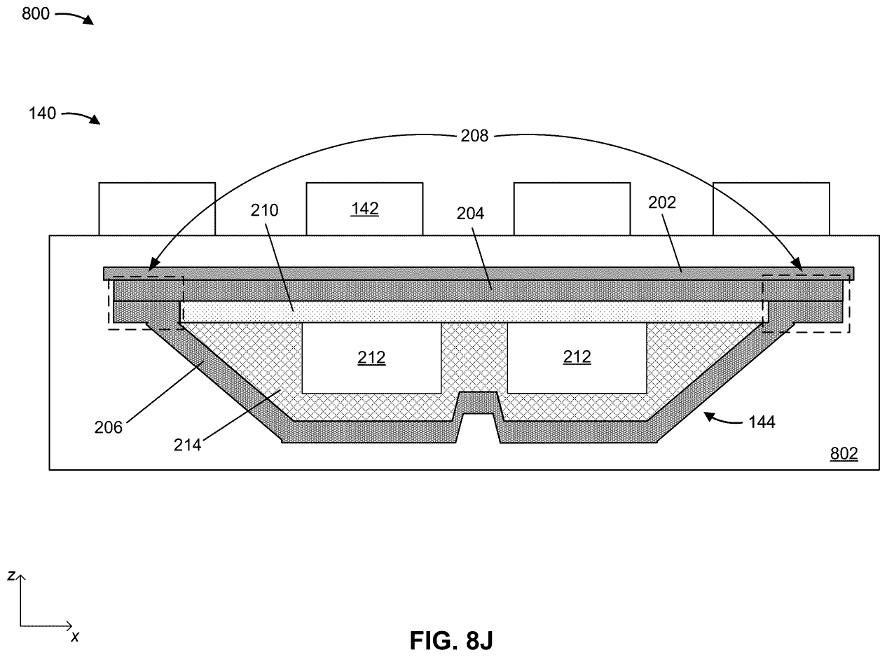

FIGS. 8A-8J are diagrams of an example implementation 800 of forming an inductive device 144 described herein. The example implementation 800 may include an example of forming the inductive device 144 in an IPD package 140 described herein. In some implementations, one or more operations of the example implementation 800 may be performed using one or more semiconductor processing tools, such as a deposition tool, an exposure tool, a developer tool, an etch tool, a planarization tool, an ion implantation tool, and/or a packaging tool, among other examples.

As shown in FIG. 8A, a portion of a body 802 of the IPD package 140 may be provided. In some implementations, the portion of the body 802 of the IPD package 140 may be provided as a substrate. The substrate may be a dielectric substrate (e.g., a silicon oxide (SiOₓ) substrate or glass substrate) and/or another type of substrate. In some implementations, the substrate is provided in the form of a wafer or another type of workpiece.

As shown in FIG. 8B, the adhesion layer 202 of the inductive device 144 may be provided over and/or on the portion of the body 802 of the IPD package 140 (e.g., over and/or on the substrate). In some implementations, the adhesion layer 202 is pre-formed and transferred to the portion of the body 802 of the IPD package 140 (e.g., using a pick-and-place tool). In some implementations, a deposition tool is used to deposit the adhesion layer 202. In these implementations, the adhesion layer 202 may be deposited using a physical vapor deposition (PVD) technique such as sputtering, a chemical vapor deposition (CVD) technique, an atomic layer deposition (ALD) technique, and/or another suitable deposition technique.

As shown in FIG. 8C, the lower magnetic layer 204 of the inductive device 144 may be provided over and/or on the adhesion layer 202. The adhesion layer 202 may promote adhesion of the lower magnetic layer 204 to the body 802 of the IPD package 140. In some implementations, the lower magnetic layer 204 is pre-formed and transferred onto the adhesion layer 202 (e.g., using a pick-and-place tool). In some implementations, a deposition tool is used to deposit the lower magnetic layer 204. In these implementations, the lower magnetic layer 204 may be deposited using a PVD technique such as sputtering, a CVD technique, an ALD technique, and/or another suitable deposition technique.

In some implementations, the magnetic material of the lower magnetic layer 204 may be deposited by in-situ doping. For example, metal elements such as cobalt (Co) and iron (Fe) may be doped during deposition with boron (B), nitrogen (N), and/or carbon (C) to deposit the magnetic material of the lower magnetic layer 204 onto the adhesion layer 202. In some implementations, the magnetic material of the lower magnetic layer 204 may be deposited by a combination of deposition (e.g., CVD, PVD, ALD) and ion implantation tool. For example, a deposition tool may be used to deposit the metal elements of the lower magnetic layer 204 onto the adhesion layer 202, and an ion implantation tool may be used to implant boron dopants, nitrogen dopants, and/or carbon dopants into the lower magnetic layer 204.

In some implementations, the metal elements of the magnetic material of the lower magnetic layer 204 may be deposited at respective deposition rates such that the concentration of iron in the lower magnetic layer 204 and the concentration of cobalt in the lower magnetic layer 204 are approximately equal. For example, the cobalt and iron may be deposited at respective deposition rates such that a ratio of iron in the lower magnetic layer 204 to cobalt in the lower magnetic layer 204 is approximately 1:1.

In some implementations, the metal elements of the magnetic material of the lower magnetic layer 204 may be deposited at respective deposition rates such that the concentration of iron in the lower magnetic layer 204 is greater than the concentration of cobalt in the lower magnetic layer 204. For example, the cobalt and iron may be deposited at respective deposition rates such that a ratio of iron in the lower magnetic layer 204 to cobalt in the lower magnetic layer 204 is greater than approximately 1:1 and up to approximately 14:3. However, other values and ranges are within the scope of the present disclosure.

In some implementations, the magnetic material of the lower magnetic layer 204 may be deposited at a temperature to achieve a particular diffusion coefficient for the nitrogen doping and/or for the carbon doping. For example, the magnetic material of the lower magnetic layer 204 may be deposited at a lower temperature to achieve a lower diffusion coefficient for the nitrogen doping and/or for the carbon doping. As another example, the magnetic material of the lower magnetic layer 204 may be deposited at a higher temperature to achieve a higher diffusion coefficient for the nitrogen doping and/or for the carbon doping.

As shown in FIG. 8D, the isolation layer 210 may be formed over and/or on the lower magnetic layer 204. The isolation layer 210 may be deposited using a PVD technique such as sputtering, a CVD technique, an ALD technique, and/or another suitable deposition technique.

As shown in FIG. 8E, sides of the isolation layer 210 may be etched back to define the wing regions 208 of the inductive device 144. In the wing regions 208, the sides of the lower magnetic layer 204 are exposed so that corresponding sides of the upper magnetic layer 206 can be formed on the sides of the lower magnetic layer 204 in the wing regions 208.

In some implementations, a pattern in a photoresist layer is used to etch the isolation layer 210 to form the wing regions 208. In these implementations, a deposition tool may be used to form the photoresist layer on the isolation layer 210 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the isolation layer 210 based on the pattern to form the wing regions 208. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the isolation layer 210 based on a pattern.

As shown in FIG. 8F, the conductor(s) 212 may be provided over and/or on the isolation layer 210. In some implementations, a processing tool is used to place the conductor(s) 212 on the isolation layer 210. In some implementations, a deposition tool is used to deposit a layer of conductive material, an exposure tool is used to form a patterned masking layer on the layer of conductive material, and the etch tool is used to etch the layer of conductive material based on the patterned masking layer to form the conductor(s) 212. In some implementations, a deposition tool is used to deposit a layer, an exposure tool and an etch tool are used to form trenches in the layer, and a deposition tool is used to deposit conductive material in the trenches to form the conductor(s) 212.

As shown in FIG. 8G, the fill layer 214 may be formed over, on, and/or around the conductor(s) 212. The fill layer may also be formed over and/or on the exposed portions of the isolation layer 210 so that the fill layer 214 and the isolation layer 210 encapsulate the conductor(s) 212. A deposition tool may be used to deposit the fill layer 214 using a PVD technique, an ALD technique, a CVD technique, an oxidation technique, and/or another suitable deposition technique.

As shown in FIG. 8H, the upper magnetic layer 206 of the inductive device 144 may be provided over and/or on the fill layer 214. In some implementations, the upper magnetic layer 206 is pre-formed and transferred onto the fill layer 214 (e.g., using a pick-and-place tool). In some implementations, a deposition tool is used to deposit the upper magnetic layer 206. In these implementations, the upper magnetic layer 206 may be deposited using a PVD technique such as sputtering, a CVD technique, an ALD technique, and/or another suitable deposition technique.

The upper magnetic layer 206 may be deposited such that sides of the upper magnetic layer 206 are deposited on exposed sides of the lower magnetic layer 204 in the wing regions 208. The upper magnetic layer 206 contacts the lower magnetic layer 204 in the wing regions 208 to form a continuous layer of magnetic material around the conductor(s) 212.

In some implementations, the magnetic material of the upper magnetic layer 206 may be deposited by in-situ doping. For example, metal elements such as cobalt (Co) and iron (Fe) may be doped during deposition with boron (B), nitrogen (N), and/or carbon (C) to deposit the magnetic material of the upper magnetic layer 206. In some implementations, the magnetic material of the upper magnetic layer 206 may be deposited by a combination of deposition (e.g., CVD, PVD, ALD) and ion implantation tool. For example, a deposition tool may be used to deposit the metal elements of the upper magnetic layer 206, and an ion implantation tool may be used to implant boron dopants, nitrogen dopants, and/or carbon dopants into the upper magnetic layer 206.

In some implementations, the metal elements of the magnetic material of the upper magnetic layer 206 may be deposited at respective deposition rates such that the concentration of iron in the upper magnetic layer 206 and the concentration of cobalt in the upper magnetic layer 206 are approximately equal. For example, the cobalt and iron may be deposited at respective deposition rates such that a ratio of iron in the upper magnetic layer 206 to cobalt in the upper magnetic layer 206 is approximately 1:1.

In some implementations, the metal elements of the magnetic material of the upper magnetic layer 206 may be deposited at respective deposition rates such that the concentration of iron in the upper magnetic layer 206 is greater than the concentration of cobalt in the upper magnetic layer 206. For example, the cobalt and iron may be deposited at respective deposition rates such that a ratio of iron in the upper magnetic layer 206 to cobalt in the upper magnetic layer 206 is greater than approximately 1:1 and up to approximately 14:3. However, other values and ranges are within the scope of the present disclosure.

In some implementations, the magnetic material of the upper magnetic layer 206 may be deposited at a temperature to achieve a particular diffusion coefficient for the nitrogen doping and/or for the carbon doping. For example, the magnetic material of the upper magnetic layer 206 may be deposited at a lower temperature to achieve a lower diffusion coefficient for the nitrogen doping and/or for the carbon doping. As another example, the magnetic material of the upper magnetic layer 206 may be deposited at a higher temperature to achieve a higher diffusion coefficient for the nitrogen doping and/or for the carbon doping.

As shown in FIG. 8I, additional material of the body 802 of the IPD package 140 may be deposited over the inductive device 144 so that the inductive device 144 is encapsulated in the body 802 of the IPD package 140. A deposition tool may be used to deposit the additional material of the body 802 of the IPD package 140 by dispensing, CVD, ALD, PVD, oxidation, spin-coating, solution-gelling, and/or another suitable deposition technique.

As shown in FIG. 8J, a wafer/die transport tool may be used to flip the IPD package 140 so that the IPD package 140 is rotated approximately 180 degrees relative to the orientation in FIG. 8H. This enables processing to be performed on the bottom of the IPD package 140. In some implementations, the IPD package 140 may be placed on a carrier substrate so that the IPD package 140 is secured to the carrier substrate during subsequent process operations.

As further shown in FIG. 8J, connection structures 142 may be attached to the IPD package 140. In some implementations, the connection structures 142 are attached to the IPD package 140 by solder flux and then soldered to the IPD package 140 (e.g., by wave soldering and/or another soldering technique). In some implementations, the connection structures 142 are attached to the IPD package 140 by bonding.

As indicated above, FIGS. 8A-8J are provided as an example. Other examples may differ from what is described with regard to FIGS. 8A-8J.

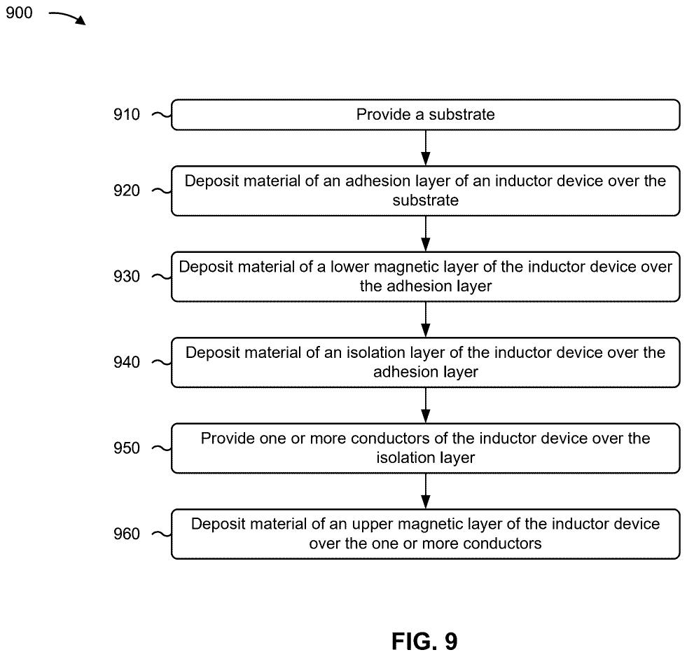

FIG. 9 is a flowchart of an example process 900 associated with forming an inductive device described herein. In some implementations, one or more process blocks of FIG. 9 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 9, process 900 may include providing a substrate (block 910). For example, one or more semiconductor processing tools may be used to provide a substrate (e.g., a portion of a body 802), as described herein.

As further shown in FIG. 9, process 900 may include depositing material of an adhesion layer of an inductive device over the substrate (block 920). For example, one or more semiconductor processing tools may be used to deposit material of an adhesion layer (e.g., an adhesion layer 202) of an inductive device (e.g., an inductive device 144) over the substrate, as described herein. In some implementations, the material of the adhesion layer includes a first metal element.

As further shown in FIG. 9, process 900 may include depositing material of a lower magnetic layer of the inductive device over the adhesion layer (block 930). For example, one or more semiconductor processing tools may be used to deposit material of a lower magnetic layer (e.g., a lower magnetic layer 204) of the inductive device over the adhesion layer, as described herein. In some implementations, the material of the lower magnetic layer includes a plurality of second metal elements.

As further shown in FIG. 9, process 900 may include depositing material of an isolation layer of the inductive device over the adhesion layer (block 940). For example, one or more semiconductor processing tools may be used to deposit material of an isolation layer (e.g., an isolation layer 210) of the inductive device over the adhesion layer, as described herein. In some implementations, the material of the isolation layer includes a third metal element. In some implementations, each of the plurality of second metal elements is different than the first metal element and the third metal element. In some implementations, the material of the lower magnetic layer is free of the first metal element and the third metal element.

As further shown in FIG. 9, process 900 may include providing one or more conductors of the inductive device over the isolation layer (block 950). For example, one or more semiconductor processing tools may be used to provide one or more conductors (e.g., one or more conductors 212) of the inductive device over the isolation layer, as described herein.

As further shown in FIG. 9, process 900 may include depositing material of an upper magnetic layer of the inductive device over the one or more conductors (block 960). For example, one or more semiconductor processing tools may be used to deposit material of an upper magnetic layer (e.g., an upper magnetic layer 206) of the inductive device over the one or more conductors, as described herein. In some implementations, the material of the upper magnetic layer is a same material as the material of the lower magnetic layer. In some implementations, portions of the upper magnetic layer are deposited on portions of the lower magnetic layer to form wing regions (e.g., wing regions 208) of the inductive device.

Process 900 may include additional implementations, such as any single implementation or any combination of implementations described below and/or in connection with one or more other processes described elsewhere herein.

In a first implementation, depositing the material of the lower magnetic layer includes doping the plurality of second metal elements with boron (B).

In a second implementation, alone or in combination with the first implementation, depositing the material of the lower magnetic layer includes doping the plurality of second metal elements with a combination of boron (B) and nitrogen (N).

In a third implementation, alone or in combination with one or more of the first and second implementations, depositing the material of the lower magnetic layer includes doping the plurality of second metal elements with a combination of boron (B) and carbon (C).

In a fourth implementation, alone or in combination with one or more of the first through third implementations, the isolation layer is a dielectric layer that contains an oxide of the third metal element.

In a fifth implementation, alone or in combination with one or more of the first through fourth implementations, the isolation layer is a dielectric layer that contains a nitride of the third metal element.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

In this way, an inductive device is manufactured to include a magnetic film scheme that increases the performance of the inductive device by increasing saturation current of the inductive device, decreasing hysteresis loss of the inductive device, and/or decreasing eddy current loss of the inductive device, among other examples. The inductive device may include a magnetic layer that includes a combination of metal elements that is doped with boron (B) to achieve low coercivity (H_{c}-resistance to becoming demagnetized) in the magnetic layer, which enables low hysteresis loss to be achieved for the inductive device. Additionally and/or alternatively to the combination of metal elements and boron doping, the magnetic layer may be doped with additional dopants such as nitrogen (N) and/or carbon (C) to increase the magnetic anisotropy of the magnetic layer and/or to increase the resistivity of the magnetic layer.

As described in greater detail above, some implementations described herein provide a semiconductor device. The semiconductor device includes one or more conductors. The semiconductor device includes a lower magnetic layer. The semiconductor device includes an upper magnetic layer, where the lower magnetic layer and the upper magnetic layer are in contact in one or more wing regions of the semiconductor device such that the lower magnetic layer and the upper magnetic layer form a continuous magnetic layer around the one or more conductors, and where the lower magnetic layer and the upper magnetic layer both include a material containing a plurality of metal elements doped with boron (B).

As described in greater detail above, some implementations described herein provide a packaged device. The packaged device includes a body. The packaged device includes one or more package connectors coupled to the body. The packaged device includes an inductive device, in the body and coupled to the one or more package connectors. The inductive device includes an adhesion layer, a lower magnetic layer over the adhesion layer, an isolation layer over the lower magnetic layer, one or more conductors over the isolation layer, a fill layer over the one or more conductors and over the isolation layer, and an upper magnetic layer over the fill layer. The lower magnetic layer and the upper magnetic layer are in contact in one or more wing regions of the inductive device such that the lower magnetic layer and the upper magnetic layer form a continuous magnetic layer around the one or more conductors. The lower magnetic layer and the upper magnetic layer both include a material containing at least cobalt (Co), iron (Fe), boron (B), and a dopant having a diffusion coefficient that is less than a diffusion coefficient of the boron.

As described in greater detail above, some implementations described herein provide a method. The method includes providing a substrate. The method includes depositing material of an adhesion layer of an inductive device over the substrate, where the material of the adhesion layer includes a first metal element. The method includes depositing material of a lower magnetic layer of the inductive device over the adhesion layer, where the material of the lower magnetic layer includes a plurality of second metal elements. The method includes depositing material of an isolation layer of the inductive device over the adhesion layer, where the material of the isolation layer includes a third metal element, where each of the plurality of second metal elements is different than the first metal element and the third metal element, and where the material of the lower magnetic layer is free of the first metal element and the third metal element. The method includes providing one or more conductors of the inductive device over the isolation layer. The method includes depositing material of an upper magnetic layer of the inductive device over the one or more conductors, where the material of the upper magnetic layer is a same material as the material of the lower magnetic layer, and where portions of the upper magnetic layer are deposited on portions of the lower magnetic layer to form wing regions of the inductive device.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
one or more conductors;
a lower magnetic layer; and
an upper magnetic layer,
wherein the lower magnetic layer and the upper magnetic layer are in contact in one or more wing regions of the semiconductor device such that the lower magnetic layer and the upper magnetic layer form a continuous magnetic layer around the one or more conductors, and
wherein the lower magnetic layer and the upper magnetic layer both comprise a material containing a plurality of metal elements doped with boron (B).

2. The semiconductor device of claim 1, further comprising:
an isolation layer between the lower magnetic layer and the one or more conductors,
wherein the isolation layer comprises a metal-oxide material that contains a metal element different than the plurality of metal elements included in the material of the lower magnetic layer and the upper magnetic layer.

3. The semiconductor device of claim 1, further comprising:
an isolation layer between the lower magnetic layer and the one or more conductors,
wherein the isolation layer comprises a metal-nitride material that contains a metal element different than the plurality of metal elements included in the material of the lower magnetic layer and the upper magnetic layer.

4. The semiconductor device of claim 1, further comprising:
an isolation layer between the lower magnetic layer and the one or more conductors,
wherein the isolation layer comprises a non-metal oxide material that contains a semiconductor element.

5. The semiconductor device of claim 1, further comprising:
an adhesion layer under the lower magnetic layer,
wherein the adhesion layer comprises a metal material that contains a metal element other than the plurality of metal elements included in the material of the lower magnetic layer and the upper magnetic layer.

6. The semiconductor device of claim 1, wherein a concentration of boron in the material of the lower magnetic layer and the upper magnetic layer is included in a range of approximately 10% by atomic volume to approximately 25% by atomic volume.

7. The semiconductor device of claim 1, wherein a grain size of the material of the lower magnetic layer and the upper magnetic layer is included in a range of approximately 1 nanometer to approximately 500 nanometers.

8. A packaged device, comprising:
a body;
one or more package connectors coupled to the body; and
an inductive device, in the body and coupled to the one or more package connectors, comprising:
an adhesion layer;
a lower magnetic layer over the adhesion layer;
an isolation layer over the lower magnetic layer;
one or more conductors over the isolation layer;
a fill layer over the one or more conductors and over the isolation layer; and
an upper magnetic layer over the fill layer,
wherein the lower magnetic layer and the upper magnetic layer are in contact in one or more wing regions of the inductive device such that the lower magnetic layer and the upper magnetic layer form a continuous magnetic layer around the one or more conductors, and
wherein the lower magnetic layer and the upper magnetic layer both comprise a material containing at least cobalt (Co), iron (Fe), boron (B), and a dopant having a diffusion coefficient that is less than a diffusion coefficient of the boron.

9. The packaged device of claim 8, wherein the dopant comprises at least one of:
nitrogen (N), or
carbon (C).

10. The packaged device of claim 8, wherein the dopant comprises a combination of nitrogen (N) and carbon (C).

11. The packaged device of claim 8, wherein the dopant and the isolation layer both contain nitrogen (N).

12. The packaged device of claim 8, wherein a concentration of the dopant in the material of the lower magnetic layer and the upper magnetic layer is less than a concentration of the boron in the material of the lower magnetic layer and the upper magnetic layer.

13. The packaged device of claim 8, wherein the adhesion layer and the isolation layer contain different metal elements.

14. The packaged device of claim 8, wherein the adhesion layer and the isolation layer contain aluminum (Al).

15. A method, comprising:
providing a substrate;
depositing material of an adhesion layer of an inductive device over the substrate,
wherein the material of the adhesion layer comprises a first metal element;
depositing material of a lower magnetic layer of the inductive device over the adhesion layer,
wherein the material of the lower magnetic layer comprises a plurality of second metal elements;
depositing material of an isolation layer of the inductive device over the adhesion layer,
wherein the material of the isolation layer comprises a third metal element,
wherein each of the plurality of second metal elements is different than the first metal element and the third metal element, and
wherein the material of the lower magnetic layer is free of the first metal element and the third metal element;
providing one or more conductors of the inductive device over the isolation layer; and
depositing material of an upper magnetic layer of the inductive device over the one or more conductors,
wherein the material of the upper magnetic layer is a same material as the material of the lower magnetic layer, and
wherein portions of the upper magnetic layer are deposited on portions of the lower magnetic layer to form wing regions of the inductive device.

16. The method of claim 15, wherein depositing the material of the lower magnetic layer comprises:
doping the plurality of second metal elements with boron (B).

17. The method of claim 15, wherein depositing the material of the lower magnetic layer comprises:
doping the plurality of second metal elements with a combination of boron (B) and nitrogen (N).

18. The method of claim 15, wherein depositing the material of the lower magnetic layer comprises:
doping the plurality of second metal elements with a combination of boron (B) and carbon (C).

19. The method of claim 15, wherein the isolation layer is a dielectric layer that contains an oxide of the third metal element.

20. The method of claim 15, wherein the isolation layer is a dielectric layer that contains a nitride of the third metal element.
